(19) United States
(12) Patent Application Publication
(10) Pub. No.: US 2020/0223206 A1
(43) Pub. Date: Jul. 16, 2020

(54) METHODS FOR PRODUCTION AND TRANSFER OF PATTERNED THIN FILMS AT WAFER-SCALE

(71) Applicant: SPECTRAL DEVICES INC.

(72) Inventors: Mohamadreza NAJIMINAINI, London (CA); Jeffrey John Leslie CARSON, London (CA)

(21) Appl. No.: 15/759,038

(22) PCT Filed: Sep. 9, 2016
(86) PCT No.: PCT/CA2016/051066

§ 371 Date: Mar. 9, 2018

(51) Int. Cl. B32B 38/10; B32B 7/06; G03F 7/00; B32B 37/00; B81C 1/00

(52) U.S. Cl. CPC B32B 38/10; B32B 7/06; B81C 2201/0194; B32B 37/025; B81C 1/00634; G03F 7/0002

(57) ABSTRACT

Methods for replication and lift-off of micro/nano structures in single or multilayer thin films from a master substrate at wafer scale. The methods utilize polymeric materials with low-elastomeric properties to enhance the mechanical strength of the thin films during the replication and liftoff process from a master substrate, wherein the flexible polymer can have stand alone integrity. The master substrate can contain a surface relief which has a desired pattern to be replicated.

### CROSS-REFERENCE

This application claims the benefit of priority to U.S. Provisional Patent Application No. 62/217,395 filed Sep. 11, 2015 entitled METHODS FOR PRODUCTION AND TRANSFER OF PATTERNED THIN FILMS AT WAFER-SCALE, the contents of which are herein incorporated by reference into the Detailed Description of Example Embodiments herein below.

### FIELD

At least some example embodiments relate to methods for replication and lift off of micro/nanostructures in a single or a multilayer thin film from a master substrate at wafer scale.

### BACKGROUND

Planar and three dimensional nano/microstructures in single or multilayer thin films have been fabricated with a variety of lithography techniques. For example, metallic nanostructures in a thin film have been produced with different fabrication tools such as electron beam lithography and focused ion beam. However, these tools are very expensive and they are capable of producing nano/microstructures over a small area suitable for research purposes, but are not suitable for high volume manufacturing. Industrial-scale manufacturing has been performed with methods such as nano-imprint lithography and laser interference lithography to produce nanostructures over large areas (e.g. wafer scale).

The optical and electrical performance of single or multilayer micro/nanostructure thin films depends significantly on surface quality requiring clean fabrication of structures. Moreover, the ability to replicate single or multilayer nano/micro structures thin films over large scale (e.g. wafer scale) with high yields have been limited due to fragility of the thin films. For example, it has been shown that imprinting and embossing techniques result in surface deformation and non-uniform nano/microstructure shape and surface quality. Conventional processes for transferring a single or multilayer thin film has generally not been successful due to the fragility of the thin film and the appearance of breaks and cracks in the film due to the elastomeric carrier, which reduce yield and degrade performance. Template stripping processes have been limited to small areas of nanostructures and result in defects across the sample. Therefore, many existing methods have been unable to produce high quality, high yield wafer scale nano/microstructures in single or multilayer thin films.

Additional difficulties with existing filters and devices may be appreciated in view of the Detailed Description of Example Embodiments, below.

### SUMMARY

In an example embodiment, there is provided a method for transferring an impression of a surface relief from a master substrate onto a thin film, the method including: coating said surface relief of said master substrate with said thin film; and coating said thin film with a protective layer, wherein said protective layer is a flexible low-elastomeric polymer; and detaching, from said master substrate, said protective layer carrying said thin film.

In an example embodiment, there is provided a surface relief impression transfer system, including: a master substrate having a surface relief; a thin film coating said surface relief of said master substrate, the thin film detachable from the master substrate; and a protective layer coating said thin film, wherein said protective layer is a flexible low-elastomeric polymer.

In an example embodiment, there is provided a method for transferring, single or multilayer micro/nanostructure thin films from a master substrate onto a low-elastomeric flexible substrate. The method includes: manufacturing a flexible single or multilayer micro/nanostructure thin films from a master substrate, which includes deposition of a release agent on the master substrate, single or multilayer thin film deposition, depositing low-elastomeric polymer and stripping of polymer and the single or the multilayer thin film.

In an example embodiment, there is provided a method for transferring and printing, single or multilayer micro/nanostructure thin films from master substrate onto a secondary substrate. The method includes: transferring a single or multilayer micro/nanostructure thin films from a master substrate and printing to a secondary substrate, which includes deposition of a release agent on a master substrate, single or multilayer thin film deposition, depositing low-elastomeric polymer, stripping of polymer and the single or the multilayer thin film, printing the flexible material onto a secondary substrate using direct or indirect bonding, and removing the deposited polymer from the single or the multilayer thin film.

In an example embodiment, there is provided a method for transferring and printing, single or multilayer micro/nanostructure thin films from a master substrate onto a secondary substrate. The method includes: transferring and printing a single or multilayer micro/nanostructure thin films from a master substrate directly onto a secondary substrate, which includes release agent deposition, single or multilayer thin film deposition, depositing low-elastomeric polymer, bonding master substrate to secondary substrate from polymer side, and detaching master substrate from secondary substrate.

In an example embodiment, there is provided a method for lifting off non-adherent material from a master substrate. The method includes: lifting off non-adhered material from a substrate surface, which includes release agent deposition and patterning, single or multilayer thin film deposition, depositing polymer, stripping of polymer and non-adhered single or multilayer thin film, and removal of polymer residue on the substrate.

In an example embodiment, there is provided a method for fabrication of multilayer micro/nanostructure using multiple transferring, printing, and deposition processes onto a secondary substrate. The method includes multiple transferring and printing of material from master substrate onto the same substrate. The method may include extra deposition on the transferred flexible single or multilayer micro/nanostructure films or the printed single or multilayer micro/nanostructure thin films.

In an example embodiment, various micro/nanostructures in single or multilayer thin films are produced. The single or multilayer thin films include metal and dielectrics such as Ag, Au, Cu, Al₂O₃, TiO₂, SiO₂, and SiN₃. In an example embodiment, micro/nanostructures can be any shape in the thin films, including symmetric and asymmetric shapes.

In an example embodiment, low-elastomeric polymer is used for preserving the single or multilayer thin film integrity during the transfer and printing process from a master substrate. Low-elastomeric polymer can include a polymer with Young's Modulus greater than 10 MPa (at least 10 times higher than common elastomeric polymers). Polymers with 500 MPa to 10 Gpa Young's Modulus are used in some example embodiments.

### BRIEF DESCRIPTION OF THE DRAWINGS

Embodiments will now be described by way of examples with reference to the accompanying drawings, in which like reference numerals may be used to indicate similar features, and in which:

FIG. 1 illustrates a flow diagram of a method for replication of micro/nanostructures in single or multilayer thin films onto flexible or secondary substrates, in accordance with an example embodiment;

FIG. 2 illustrates a flow diagram of a method for replication of micro/nanostructures in single or multilayer thin films directly onto a secondary substrate, in accordance with an example embodiment;

FIG. 3 illustrates a flow diagram of a method for lift-off non-adhered single or multilayer films from a substrate, in accordance with an example embodiment;

FIG. 4(a) illustrates step-by-step schematic of the replication fabrication process demonstrating how a nano-hole array in gold film is transferred from a silicon substrate and printed onto a glass substrate;

FIG. 4(b) illustrates an image (originally taken in color) of a large nano-hole array transferred onto a Polydimethylsiloxane (PDMS) slab from a nano-hole array in aluminum;

FIG. 4(c) illustrates a scanning electron microscope (SEM) image of a nano-hole array fabricated with replication method onto a Pyrex™ substrate and etched with oxygen plasma;

FIG. 5(a) illustrates schematic diagram of the printing process to create second nano-hole array layer using a 2 replication step process;

FIG. 5(b) shows SEM image after FIB milling showing a cross-sectional view of a double-layer gold nano-hole array after oxygen plasma etching that was fabricated in 2 replication steps;

FIG. 5(c) illustrates schematic diagram of a cross-sectional view of a double-layer nano-hole array with a SiO₂ intermediate layer between the two gold nano-hole array layers;

FIG. 5(d) shows SEM image after focused ion beam (FIB) milling showing a cross-sectional view of the double-layer nano-hole array with the SiO₂ intermediate layer that was fabricated in a single replication step;

FIG. 6 illustrates a pixelated wire grid polarizer in silicon master substrate, wherein (a) shows photograph image of silicon substrate with indicated wire grid polarizer device in the middle (2 mm by 2 mm), (b) shows optical reflection images from silicon pixelated wire grid polarizers at different magnifications, and (c) shows SEM images of pixelated wire grid polarizers in silicon substrate at different magnifications;

FIG. 7 illustrates a replicated pixelated wire grid polarizer in 100-nm thick gold film on a Pyrex substrate, wherein (a) shows photograph of the replicated wire grid polarizer in a 100-nm gold film on Pyrex substrate, (b) shows optical reflection images of the gold pixelated wire grid polarizers at different magnifications, (c) shows SEM images of the pixelated wire grid polarizer in 100-nm gold film on Pyrex substrate at various magnifications; and

FIG. 8 illustrate a replicated pixelated wire grid polarizer in 100-nm thick gold film on a flexible substrate, wherein (a) shows photograph of the replicated wire grid polarizer in a 100-nm gold film on flexible substrate, and (b) shows optical reflection images of the gold pixelated wire grid polarizer at various magnifications.

### DETAILED DESCRIPTION OF EXAMPLE EMBODIMENTS

In an example embodiment, there is provided a method for transferring an impression of a surface relief from a master substrate onto a thin film, the method including: coating said surface relief of said master substrate with said thin film; and coating said thin film with a protective layer, wherein said protective layer is a flexible low-elastomeric polymer; and detaching, from said master substrate, said protective layer carrying said thin film.

In an example embodiment, there is provided a surface relief impression transfer system, including: a master substrate having a surface relief; a thin film coating said surface relief of said master substrate, the thin film detachable from the master substrate; and a protective layer coating said thin film, wherein said protective layer is a flexible low-elastomeric polymer.

Planar and three dimensional nano/microstructures in single or multilayer thin films have been fabricated with a variety of lithography techniques. For example, metallic nanostructures in a thin film have been produced with different fabrication tools such as electron beam lithography and focused ion beam. However, these tools are very expensive and they are capable of producing nano/microstructures over a small area suitable for research purposes, but not suitable for high volume manufacturing. Industrial-scale manufacturing has been performed with methods such as nano-imprint lithography and laser interference lithography to produce nanostructures over large areas (e.g. wafer scale). For example, Y. Chuo et. al., “Method for fabrication of nano-structures”, U.S. Patent Application No. 2014/0093688, teaches that a master stamp with an array of nano-cones can be used for rapid roll to roll fabrication of nano-holes pattern onto the soft materials such as polymers. Some replication techniques have been introduced for producing patterns and transferring material from a master template such as template-stripping and nano-transfer printing. For example, Chanda, et al., “Large-area flexible 3D optical negative index metamaterial formed by nanotransfer printing”, Nat Nano 6, 402-407 (2011), incorporated herein by reference, teaches that nano-transfer printing (nTP) of a metamaterial with transfer from a master substrate to a target substrate using an intermediate elastomeric slab can been performed at the 4-inch wafer scale. D. Bhandari et. al., “Nanotransfer printing using plasma etched silicon stamps and mediated by in situ deposited fluoropolymer”, J. Am. Chem. Soc. 133, 7722-7724 (2011) and J. Zaumseil, et al., “Three-dimensional and multilayer nanostructures formed by nanotransfer printing”, Nano Letters 3, 1223-1227 (2003), both incorporated herein by reference, teach that nTP methods can be utilized for fabrication of dispersed metallic nano-particle patterns. P. Jia, et. al., “Plasmonic nanohole array sensors fabricated by template transfer with improved optical performance”, Nanotechnology 24, 195501 (2013), incorporated herein by reference, teach that nanohole arrays in a thin metal film can be transferred from a master silicon substrate onto an elastomeric PDMS slab. C. Schaper, U.S. Pat. No. 7,345,002 B2 (2008), incorporated herein by reference, teaches that water soluble polymer can be used to replicate and transfer patterns from a master substrate to a target substrate.

The optical and electrical performance of single or multilayer micro/nanostructure thin films depends significantly on surface quality requiring clean fabrication of structures. Moreover, the ability to replicate single or multilayer nano/micro structures thin films over large scale (e.g. wafer scale) with high yields have been limited due to fragility of the thin films. For example, it has been shown that imprinting and embossing techniques result in surface deformation and non-uniform nano/microstructure shape and surface quality. The nTP process for transferring a single or multilayer thin film has not been successful due to the fragility of the thin film and the appearance of breaks and cracks in the film due to the elastomeric carrier, which reduce yield and degrade performance. Template stripping processes have been limited to small areas of nanostructures and result in defects across the sample. Therefore, many existing methods have been unable to produce high quality, high yield wafer scale nano/microstructures in single or multilayer thin films.

In at least some example embodiments, reference to sub-wavelength can include a nano-structure or defined aperture, or defined pillar, or defined particle, which is smaller than the wavelength of the electromagnetic field, radiation and/or light incident upon that structure or defined aperture. Similarly, in some example embodiments, any reference to “nano” herein can be similarly modified, configured or applied to other sizes of structures, including pico or smaller, micro or larger, depending on the particular application and/or the incident electromagnetic field.

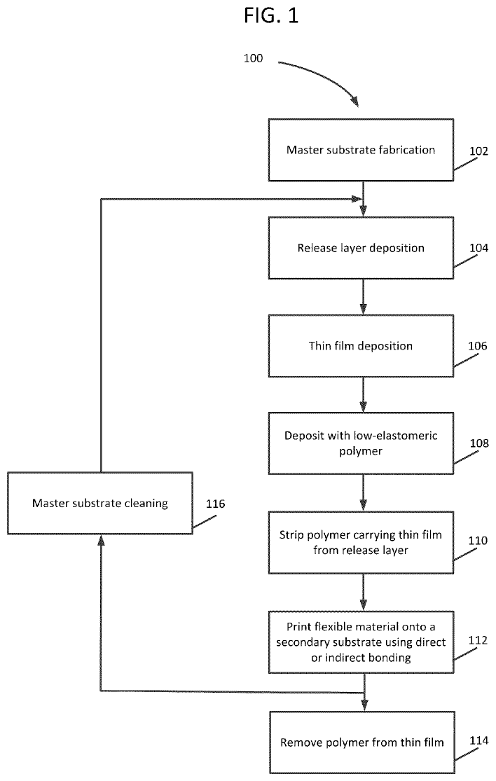

Reference is now made to FIG. 1. A replication method 100 for manufacturing a single layer or multilayer micro/nanostructure thin film from a master substrate is provided in FIG. 1. First, a master substrate fabrication process 102 is used to produce a master substrate, which includes the fabrication of micro/nano structures in master substrate, or sub-wavelength structures, in some example embodiments. Various lithography tools with deposition and etching can be used for creating a master substrate with micro/nanostructures. Lithography tools are not limited to, but include photolithography, electron beam lithography, and laser interference lithography. The master substrate can be made of materials such as silicon, silicon dioxide, silicon nitride, metals or a combination of different materials. The master substrate now contains a surface relief or pattern of interest having an impression which is desired to be transferred. After designing and fabricating the master substrate, a release agent is deposited on the surface of the master substrate (process 104) to facilitate the stripping process 110 of the apparatus from the master substrate. The release agent can be patterned onto the substrate for striping a desired region. Then, a single or multilayer thin film material is deposited on the master substrate (process 106). Various deposition tools can be used for thin film depositions such as electron beam physical vapor deposition, chemical vapor deposition, sputtering, atomic layer deposition, and epitaxial growth. The thin film thickness can be sub-nanometer to a few micrometers thick. To improve mechanical strength of single or multilayer thin film in stripping process 110 from master substrate, low-elastomeric polymer is deposited on the single or multilayer thin film (process 108). In some example embodiments, low-elastomeric polymer can be spin-coating UV/thermal curable polymers such as Benzocyclobutene (BCB), SUB, Poly(methyl methacrylate) (PMMA), and spin-on-glass (SOG). The deposited polymer can be in range of a few tens of nanometers to a few millimeters thick. Detachment of the flexible polymer and a single or multilayer thin film from the master substrate is facilitated using a stripping process 110 that separates the entire flexible polymer and single or multilayer thin film from the master substrate. The resulting detached apparatus can be attached, bonded, or printed onto a secondary substrate (process 112). Finally, the low-elastomeric polymer can be removed (process 114). The master substrate can be washed and cleaned (process 116) for the next replication process of the next apparatus (e.g. the next thin film and protective layer).

In some example embodiments, low-elastomeric polymers include polymers with higher Young's Modulus at least one order of magnitude higher than regular elastic PDMS (Young's Modulus less than 1 MPa) material. Moreover, a low-elastomeric polymer may further include a Young's Modulus between 500 MPa and 10 GPa to facilitate the transfer and printing process.

In an example embodiment, the replication method 100 for manufacturing multilayer thin films can be used several times to print nano/microstructures with the same or different materials on top of each other on the same secondary substrate. In an example embodiment, the transferred flexible single or multilayer micro/nanostructure thin films may be used as a final apparatus or attached to another apparatus. One skilled in the art may recognize that the flexible polymer carrying the single or multilayer thin film can have stand alone integrity.

In an example embodiment, instead of thermal or UV curable material in process 108, solid plastic material can be placed on the surface of the single or multilayer thin film and the temperature can be raised to allow the plastic to reach its glass transition temperature (or melting point) and then cooled down to adhere to the surface of the thin film. The plastic acts as a low-elastomeric material enabling subsequent transfer and print processes. Suitable plastics are PET, Polycarbonate, and Nylon. In some example embodiments, different low-elastomeric polymer deposition methods can be used such as sputtering, evaporation, and spraying.

In an example embodiment, the release agent can be a sacrificial layer for etching and releasing the thin film from the master substrate.

In an example embodiment, the release agent can be materials such as gold film on silicon oxide surface, fluoropolymer and 1H,1H,2H,2H-Perfluorodecyltrichlorosilane (known as FDTS).

In an example embodiment, removing 114 of the protective layer can be performed with a dry or wet etch process. In some example embodiments, fabricating the protective layer can include: fabricating with spin-coating UV-thermal curable polymers; fabricating with at least one of evaporation, sputtering, and/or spraying; fabricating with laminar polymers; or fabricating with melting and solidifying plastic sheets.

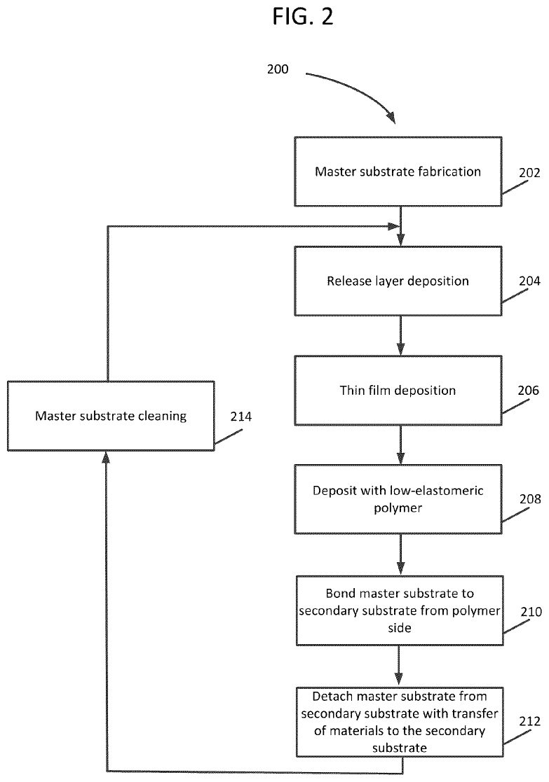

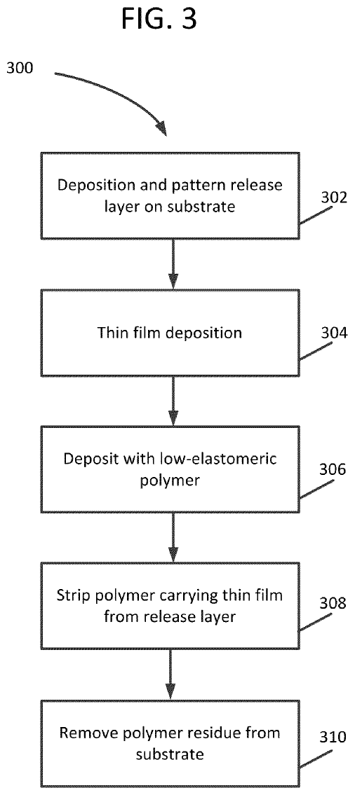

A replication method 200 for manufacturing single or multilayer micro/nanostructure thin films from a master substrate directly onto a secondary substrate is provided in FIG. 2. First, a master substrate is fabricated (process 202). The master substrate fabrication process can be similar to process 102. A release agent is deposited (process 204) on to the surface of the master substrate to facilitate the detachment of the master substrate (at process 212) from the single or multilayer micro/nanostructure thin film. Then, a single or multilayer thin film is deposited on to the master substrate (process 206). Similar to process 106, the thin film can be deposited using various deposition methods. To improve mechanical strength of the single or multilayer thin film enabling clean transfer of the thin film to the secondary substrate, a low-elastomeric polymer is deposited on to the surface of the single or multilayer thin film (process 208). Examples of low-elastomeric material, include but are not limited to Benzocyclobutene (BCB), SUB, Poly(methyl methacrylate) (PMMA), and spin-on-glass (SOG), as understood in the art. Process 208 is followed by bonding the top surface of the polymer layer on top of the master substrate to a secondary substrate (process 210). After bonding, the master substrate is then detached from the thin film (process 212), which results in a clean transfer of the single or multilayer micro/nanostructure onto the secondary substrate. The master substrate can be washed and cleaned (process 214) prior to the next replication process.

In an example embodiment, deposition of the release agent can be in pattern to facilitate detachment from predefined areas of the master substrate. This is useful when it is desirable to transfer the thin film to predefined areas of the secondary substrate, such as a silicon wafer prepared with image sensor electronics, or a patterned silicon wafer.

In an example embodiment, the replication method 200 for manufacturing multilayer thin films can be used several times to print nano/microstructures with same or different materials on top of each other on the same secondary substrate. In an example embodiment, bonding the polymer layer resulting from process 208 to the secondary substrate (at process 210) can be done through an indirect bonding process. In indirect bonding process, some thermal or UV curable adhesive material may be added onto the secondary substrate before bonding process.

The secondary substrate (at process 210) can, for example, include at least one of glass, a flexible material, a display, a window, a polymer, metal, a semiconductor, a sensor, an image sensor, a light, a tip of a fiber optic cable, a lens, a mirror, a pixelated nanohole array, a color filter array, a single layer thin film, or a multilayer thin film.

A method 300 for lifting off non-adhered single or multilayer films from a substrate is provided in FIG. 2. First, release agent is deposited on a substrate to produce a patterned release layer on the substrate (process 302). Then, a single or multilayer film is deposited on to the release layer (process 304). To facilitate lift-off, a low-elastomeric polymer is deposited on to the surface of the single or multilayer thin film (process 306). Suitable low-elastomeric materials include, but are not limited to BCB, SUB, PMMA, and SOG. Next, the polymer coated thin film is stripped from the substrate (process 308). The process results in a polymer film patterned with thin film in areas where the release agent was originally patterned onto the substrate. In other words, the thin film adhered to the substrate remains on the substrate and the rest is lifted off. Finally, a residue of polymer on the substrate can be cleaned and removed (process 310) and the substrate reused.

In an example embodiment, the liftoff method 300 can be used for lifting off non-adhered films from other materials on a substrate. For example, various materials are deposited and patterned onto the substrate and the lift-off process 300 is utilized to remove materials that are not adhered to the substrate and not adhered to the material underneath. One skilled in the art may recognize that the adherence of material is not only dependent on non-adhesive properties of material with respect to each other, but also to the structures on the substrates as well as etching and deposition methods. In an example embodiment, an elastomeric polymer block can be used to aid in the liftoff method 300.

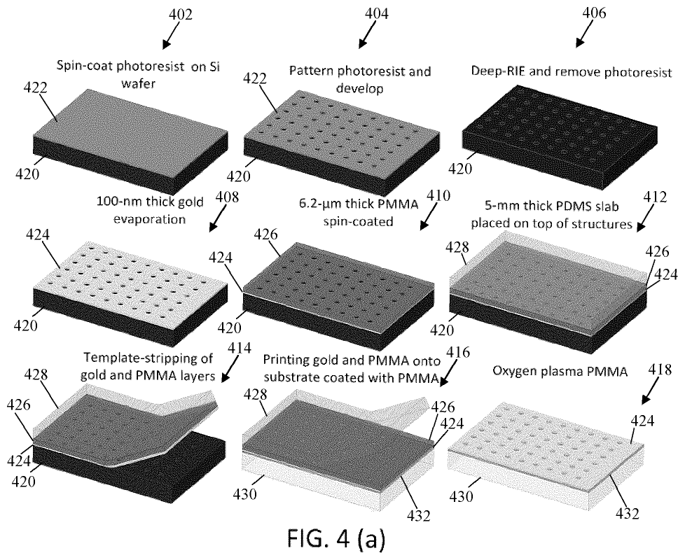

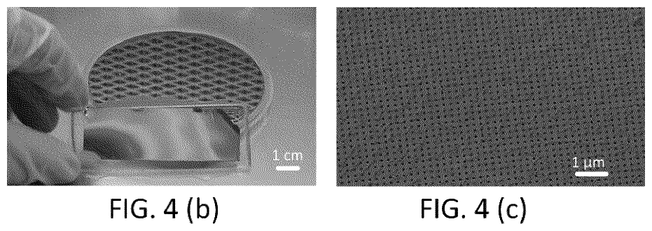

To provide an example for replication method of 100, a single layer nano-hole array in a 100-nm gold film was transferred and printed onto a secondary substrate from a master substrate. FIG. 4 (a) displays the step-by-step fabrication of a nano-hole array by replication method 100, in an example embodiment. First, at event 402, the pattern of a nanohole array was fabricated into a silicon master substrate 420. Fabrication included writing the nano-hole array pattern with electron beam lithography (EBL; LEO, 1530 e-beam lithography, Zeiss, Oberkochen, Germany) onto 200-nm thick positive-tone photoresist 422 (ZEP 520, ZEON Corporation, Tokyo, Japan) on a Si substrate 420 (100 mm diameter, 500 nm thick, SVM corporation, Santa Clara, Calif., USA). After EBL, at event 404, the photoresist 422 on the Si substrate 420 was developed (ZEP-N50, ZEON Corporation), which left behind a nano-hole array pattern in the photoresist 422. At event 406, to transfer the nano-hole array pattern from the photoresist 422 to the Si substrate 420, the sample was treated with deep reactive ion etching (DRIE; 601E Deep Silicon Etch, Alcatel, Paris, France) for 20 seconds that resulted in blind 400-nm-deep nanoholes in the top surface of the silicon wafer 420. Still referring to event 406, after removing the photoresist 406 with photoresist remover (DMAC, ZEON Corporation), the silicon wafer 420 was thermally annealed for 4 minutes at 900° C., which left behind a thin layer of SiO₂ on the surface of the silicon substrate 420. The SiO₂ layer resulted in a surface that was less adhesive to gold. In another example, fabrication of a nano-hole array with a dimension equal to 2.5 cm by 7.5 cm was accomplished with a master substrate that had a nano-hole array in an aluminum film (nano-hole diameter of 200-nm and periodicity of 480-nm, Moxtek, Orem, Utah, USA). The top surface of the master substrate 420 was first sputtered (Auto500, Edwards Company, Crawley, England) with a 40-nm thick layer of SiO₂ to reduce gold adhesion. Sputtering was followed, at event 408, by electron beam physical vapor deposition (EB-PVD) of a 100-nm thick gold film 424. At event 410, the surface of gold-film 424 was spin-coated with 6.2 μm thick polymethyl methacrylate (PMMA 950 A8, MicroChem, Newton, Mass.) 426 to enhance the mechanical strength and integrity of the gold film 424 during the transfer and printing process. The PMMA 426 was soft-baked for 3 minutes at 180° C. and bonded to the gold nano-hole array of the gold film 424. The PMMA 426 on the edges of the master substrate 420 was removed with acetone to prevent bonding between the PMMA film 426 and the master substrate 420 at the perimeter. At event 412, a cured PDMS (Sylgard 184, Dow Corning, Midland, Mich.) slab 428 with 4-mm thickness was used as a transfer carrier of a 100-nm thin film and 6.2 μm thick PMMA film 426 and was placed in conformal contact with the 6.2 μm thick PMMA 426 on the master substrate. The PDMS slab 428 extended beyond the edges of the master substrate 420 to provide better conformal contact between the PMMA 4246 and the PDMS slab 428. At event 414, manual template stripping was performed by lifting the PDMS slab 428. We observed excellent attachment between the PMMA-gold layers 424, 426 and the PDMS slab 428, and complete removal of the intact PMMA-gold layers 424, 426 from the master substrate 420. The top surface of the gold film 424 had surface roughness properties similar to the master substrate 420 surface when viewed under scanning electron microscope (1540XB FIB/SEM, Zeiss) and only a few minor cracks and breaks, which were likely related to the manual stripping procedure. At event 416, the PDMS slab 428 can be placed or have the PMMA-gold layers transferred onto a target substrate 430 (e.g. Pyrex™) which itself can be pre-coated with PMMA 432. The PDMS slab 428 can be manually template stripped off of the target substrate 430, and leaving the PMMA-gold layers 424, 426. At event 418, oxygen plasma can be used to strip at least some of the PMMA 426, 432.

FIG. 4 (b) displays an image (originally taken in color) of the resultant large nano-hole array with 2.5 cm by 7.5 cm area after template stripping with PDMS slab from the SiO₂-coated aluminum master substrate. We printed the PMMA-gold layer from the PDMS slab to the target substrate using the following steps. The target substrate was spin-coated with PMMA (PMMA 950 A2, MicroChem, Newton, Mass.) to a thickness of 360 nm and soft-baked for 3 minutes at 180° C. Next, the PDMS slab carrying the gold-PMMA layers was placed against the warmed (130° C.) target substrate and light, but uniform pressure was applied to the top of the PDMS slab to enhance contact. The PMMA on the target substrate was adhesive at 130° C. (above glass transition of PMMA) and enhanced the attachment of the gold film to the PMMA film on the target substrate. The PDMS slab was manually template-stripped and resulted in a four layer structure comprised of the target substrate on the bottom followed by an intermediate layer of PMMA, a nano-hole array carrying gold film, and a top layer of PMMA. The four layer structure was treated with oxygen plasma for 40 minutes, which resulted in near complete etching of the top layer of PMMA and cavities beneath the nano-holes in the intermediate layer of PMMA between the gold nano-hole array and the target substrate.

FIG. 4 (c) displays the top view of the nano-hole array in a gold film on a Pyrex substrate fabricated with replication method 100. The nano-hole array had high-quality nano-holes with smooth and uniform edges. Visual and SEM inspection of the nano-hole array revealed only a few breaks and cracks in the gold film. However, some PMMA residue was observed on the surface of gold film. It is anticipated that oxygen plasma treatment at higher temperatures would facilitate complete PMMA removal. The master substrate and PDMS slab were reusable for repetitive replication process. To reuse the Si master substrate, gold particles and PMMA residues inside the nano-holes were removed with exposure to acetone and gold etchant.

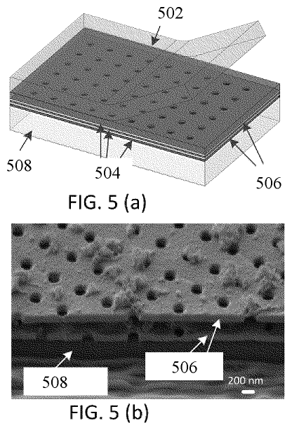

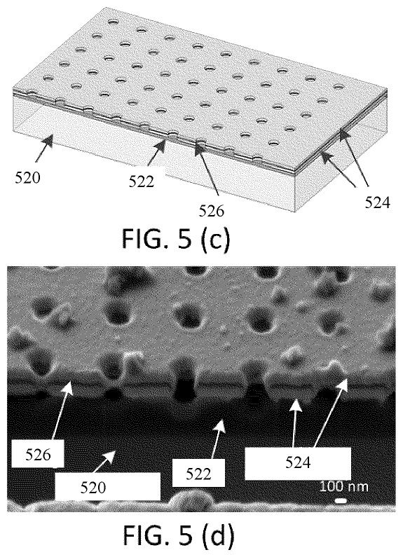

To provide an example for replication method 100 for multilayer nanostructure thin films, a double layer nano-hole array in gold film was transferred and printed onto a secondary substrate from the master substrate. To fabricate a double-layer gold nano-hole array, we used two different approaches. The first approach was to print a nano-hole array layer two times one on top of the other using two times replication method 100. The first nano-hole array layer with a few microns thick PMMA was transferred and printed onto a Pyrex substrate coated with a 360-nm thick layer of PMMA using the replication method of 100 and was followed by oxygen plasma etching of the PMMA on the gold film. Then, a 360-nm thick layer of PMMA was spin-coated on the top surface of the printed nano-hole array and was used as a bonding layer for printing of the second nano-hole array layer. The second 100-nm thick nano-hole array layer was printed on the top of the first PMMA-coated nano-hole array layer using a second replication method of 100 and is shown schematically in FIG. 5 (a) for the condition where the PDMS slab 502 is lifted off of the PMMA 504. The result was a double-layer nano-hole array left behind on the Pyrex substrate 508 with dielectric layers of PMMA 504 between gold nano-hole array layers 506. We furthermore processed the device by oxygen plasma etching the two PMMA layers 504 closest to the top surface for 1 hr to permit characterization of the double-layer nano-hole array structure by SEM. The SEM image for the double-layer nano-hole array with a nano-hole periodicity of 475 nm and a 100-nm thick gold film 506 is shown in FIG. 5 (b), supported by the Pyrex substrate 508. The SEM images revealed that the gold nano-hole array layers 506 were not coaxially aligned with respect to the nano-holes. Also, PMMA 504 residue was apparent on the top surface of the structure.

Reference is now made to FIGS. 5 (c) and 5 (d). The second approach to double-layer nano-hole array fabrication was to deposit a metal-dielectric-metal onto the master substrate and perform a single replication method of 100 to print the double-layer nano-hole array onto the target substrate 520. The master substrate was coated with an 80-nm thick gold layer using an evaporation system, a 40-nm thick layer of SiO₂ with the sputtering system, and a second 80-nm thick gold layer with the evaporation system. A 3-nm thick Ti layer was deposited prior to sputtering of the SiO₂ layer. After deposition of the second gold film, replication method of 100 was employed to transfer and print the Au—SiO₂—Au double-layer nano-hole array onto a PMMA-coated (522) Pyrex substrate 520. Afterwards, PMMA on the top layer of gold 524 was removed by oxygen plasma, thereby revealing the double-layer nano-hole array structure consisting of Au—SiO2-Au (gold 524, SiO2 526, and gold 524), which is shown in the schematic and SEM images in FIGS. 5 (c) and (d), respectively. The SEM image (FIG. 5 (d)) revealed that the gold nano-hole array layers 524 were coaxially aligned with respect to the nano-holes, for example any surface relief pattern is coaxially aligned.

To provide an example for replication method of 200 for a single layer nanostructure thin film, single layer wire grid polarizers were replicated in a gold film and the transferred to a secondary substrate using replication method 200. To fabricate the master substrate, a 200-nm thick photoresist was spin-coated onto the surface of 4-inch Silicon wafer (100 mm diameter, 500 nm thick, SVM corporation, Santa Clara, Calif., USA) and patterned with electron beam lithography machine (EBL; LEO, 1530 e-beam lithography, Zeiss, Oberkochen, Germany). The patterns consisted of pixelated wire grid polarizers with wire grids in four different orientation angles (0, 45 90, and 135 degree) in silicon substrate. The entire fabricated device dimension is 2 mm by 2 mm. Each wire grid polarizer is about 6.4 nm by 6.4 nm and the spacing between adjacent wire grid polarizers is 1 nm. The line spacing between wires is about 140 nm and the line width of each wire was measured about 85 nm. A DRIE machine was employed to transfer patterns into the silicon wafer with a pattern depth of 250 nm. The silicon wafer was then coated with 10 nm SiO₂ as a release layer for the gold film.

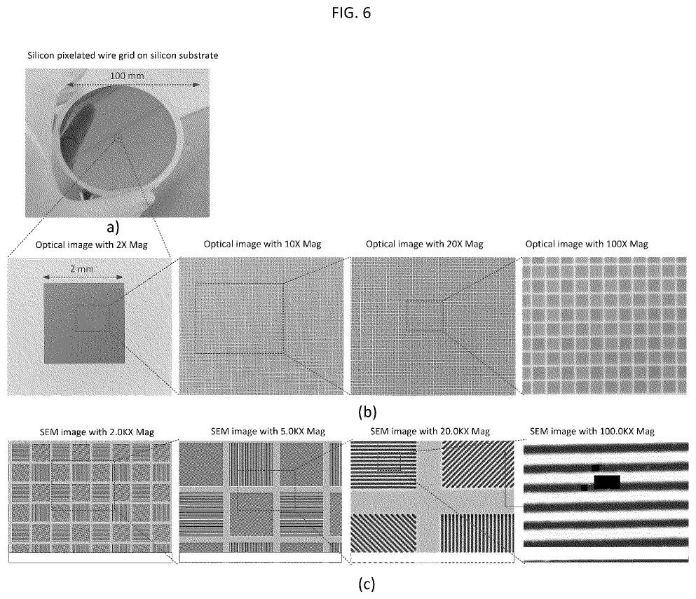

FIG. 6 at (a) (b) and (c) displays a photograph, reflection images and SEM images, respectively, of pixelated wire grid polarizer with wire grids in four different orientation angles (0, 45 90, and 135 degree) the silicon substrate. The line spacing between wires is about 140 nm and the line width of each wire was measured about 85±5 nm. A 100-nm thick gold film was deposited onto the silicon master substrate followed by spin-casting 1 μm BCB material onto the surface of gold film for enhancing mechanical strength of thin film during the transfer process onto the secondary substrate. Then, the master substrate and secondary substrate (4-inch Pyrex wafer, Pyrex 7740 from semi wafer Inc.) was placed inside 4-inch thermal-press wafer bonding machine to bond the BCB material on the master substrate to the Pyrex substrate. Vacuum and 2 or 4 bar pressure was applied between the two wafers and the temperature was raised to 230° C. for one hour to fully cure the BCB material between master and secondary substrates in the 4-inch wafer bonding machine. Then, the master substrate was detached from the Pyrex substrate and resulted in transfer of the entire gold film from the 4-inch master substrate onto the Pyrex secondary substrate, including the gold wire-grid polarizer patterns.

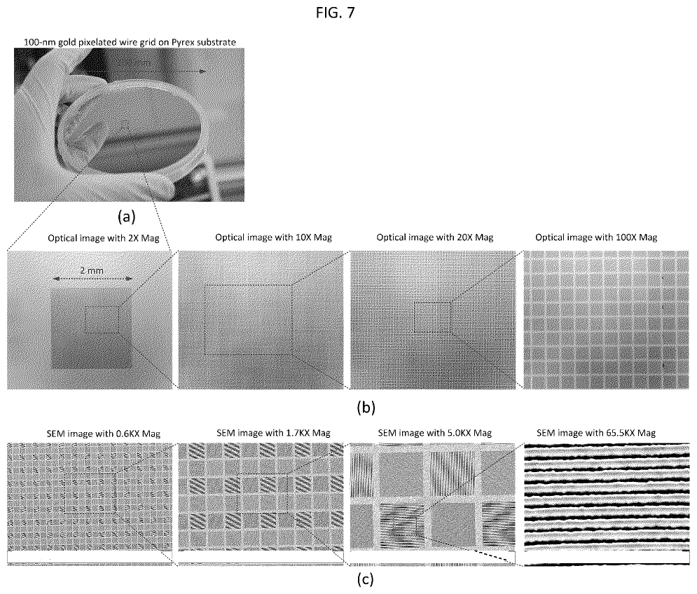

FIG. 7 at (a), (b), (c) displays a photograph, optical reflection images and SEM images, respectively, of replicated pixelated wire grid polarizer fabricated in a 100-nm thick gold film on Pyrex substrate. The entire 4-inch wafer from Silicon master substrate was replicated in 100-nm gold film on Pyrex substrate using replication method 200. Specifically, the wire grid polarizers from the silicon master substrate were completely and successfully replicated in the 100-nm gold film on Pyrex secondary substrate. The line width of wires was measured to be 95 nm±10 nm, which was almost 10 nm larger than the wire grids on silicon substrate.

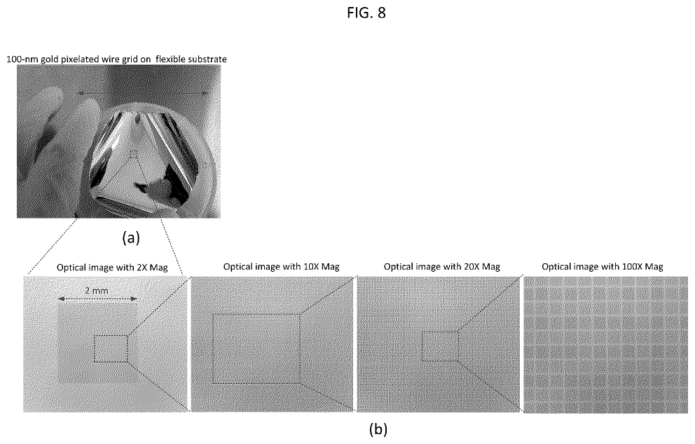

To provide an example for a part of replication method 100 for a single layer nanostructure thin film on flexible substrate, a single layer pixelated wire grid polarizer in a gold film was replicated on to a flexible substrate using a part of replication method of 100. We used the same aforementioned silicon master substrate for replication of the wire-grid polarizers in 100-nm thick gold film on flexible substrate. A 100-nm thick gold film was evaporated on 4-inch silicon master substrate using electron beam physical vapor deposition. Then, 20-μm thick SU8 was spin-coated on top of the gold film and UV/thermal cured, except at the edges of the wafer, and finally developed in SU8 developer. Then, the SU8 polymer with gold on the surface of silicon was stripped from silicon surface. In this example, SU8 polymer was used as a flexible substrate for wire grid polarizes. FIG. 8 at (a) and (b) displays a photograph and optical reflection images, respectively, of the replicated pixelated wire grid polarizer fabricated in a 100-nm thick gold film on the flexible substrate. The entire 4-inch wafer from silicon master substrate was replicated in 100-nm gold film on flexible substrate using a part of replication method of 100. Specifically, the wire grid polarizers from silicon master substrate were successfully replicated in 100-nm gild film on Pyrex substrate. The measured yield for the replicated wire grid polarizer in 100-nm gold film on Pyrex substrate was above 99% and there was no observable defects seen from replicated device except those which already existed on the master substrate, which were then replicated on the flexible device.

In some example embodiments, the pattern to be replicated can include at least one or a combination of a line grid, a wire grid, a pixelated wire grid, a nanohole array, or a pixelated nanohole array.

As can be appreciated, the master substrate fabricated with an additive manufacturing method, a subtractive manufacturing method, or lithography.

In an example embodiment, the thin film includes a single layer of metal, dielectric, or semiconductor. In an example embodiment, the thin film includes a metamaterial or metasurfaces. In an example embodiment, the thin film includes a multilayer stack wherein surface relief features in each layer of the multilayer stack are substantially identical and aligned vertically.

Certain adaptations and modifications of the described embodiments can be made. For example, in some example embodiments, the master substrate can have a surface relief which is flat, convex, concave, with or without a pattern. In an example embodiment, the master substrate has a surface which is an optical flat. In such embodiments, for example, any of these types of surface reliefs may be transferred to the thin film, carried by the protective layer.

The above discussed embodiments are considered to be illustrative and not restrictive. Example embodiments described as methods would similarly apply to systems, and vice-versa.

Variations may be made to some example embodiments, which may include combinations and sub-combinations of any of the above. The various embodiments presented above are merely examples and are in no way meant to limit the scope of this disclosure. Variations of the innovations described herein will be apparent to persons of ordinary skill in the art, such variations being within the intended scope of the present disclosure. In particular, features from one or more of the above-described embodiments may be selected to create alternative embodiments comprised of a sub-combination of features which may not be explicitly described above. In addition, features from one or more of the above-described embodiments may be selected and combined to create alternative embodiments comprised of a combination of features which may not be explicitly described above. Features suitable for such combinations and sub-combinations would be readily apparent to persons skilled in the art upon review of the present disclosure as a whole. The subject matter described herein intends to cover and embrace all suitable changes in technology.

1. A method for transferring an impression of a surface relief from a master substrate onto a thin film, the method comprising:
coating said surface relief of said master substrate with said thin film, the thin film being prone to breaks and cracks; and
coating said thin film with a removable protective layer, wherein said removable protective layer is a flexible low-elastomeric polymer and has stand alone integrity;
detaching, from said master substrate, said removable protective layer carrying said thin film.

2. The method of claim 1, further comprising coating said master substrate with a release agent.

3. The method of claim 2, where said release agent is a sacrificial layer for etching and releasing said thin film from said master substrate.

4. (canceled)

5. The method of claim 1, wherein said thin film comprises a single layer of metal, dielectric, or semiconductor.

6. The method of claim 1, wherein said thin film comprises a multilayer stack comprised of one or more metals, dielectrics, and/or semiconductors.

7. The method of claim 1, wherein said thin film comprises a multilayer stack wherein surface relief features in each layer of the multilayer stack are substantially identical and aligned vertically.

8. (canceled)

9. The method of claim 1, further comprising cleaning said master substrate after detaching said removable protective layer carrying said thin film from said master substrate, enabling a further transferring of the surface relief from the master substrate onto a second thin film.

10. The method of claim 9, further comprising coating the surface relief of the master substrate with the second thin film.

11. The method of claim 2, wherein said master substrate is coated with the release agent in a pattern.

12. (canceled)

13. (canceled)

14. The method of claim 1, wherein said surface relief of master substrate is patternless.

15. (canceled)

16. The method of claim 1, further comprising bonding said removable protective layer carrying said thin film from either protective layer side or thin film side to a secondary substrate.

17. (canceled)

18. The method of claim 1, further comprising bonding said removable protective layer to a secondary substrate before said detaching said thin film and said removable protective layer from the master substrate.

19. The method of claim 18, wherein said detaching comprises detaching said secondary substrate which carries said removable protective layer and said thin film from the master substrate.

20. (canceled)

21. (canceled)

22. The method of claim 1, further comprising removing at least part of said removable protective layer carrying said thin film from said thin film.

23. The method of claim 22, wherein said removing of said removable protective layer is performed with a dry or wet etch process.

24. The method of claim 1, wherein the coating further comprises fabricating said removable protective layer further comprises fabricating with at least one of spin-coating UV-thermal curable polymers, evaporation, sputtering, and/or spraying, or fabricating with one or more laminar polymers, or fabricating with melting and solidifying one or more plastic sheets.

25. (canceled)

26. (canceled)

27. (canceled)

28. The method of claim 1, wherein said flexible low-elastomeric polymer comprises a plastic, Benzocyclobutene (BCB), SUB, Poly(methyl methacrylate) (PMMA), or spin-on-glass (SOG).

29. (canceled)

30. The method of claim 1, wherein said low-elastomeric polymer has a Young's Modulus of at least 10 Mpa.

31. The method of claim 1, wherein said removable protective layer has more than one low-elastomeric polymer.

32. (canceled)

33. A surface relief impression transfer system, comprising:
a master substrate having a surface relief;
a thin film for coating said surface relief of said master substrate, the thin film detachable from the master substrate, the thin film being prone to breaks and cracks; and
a removable protective layer for coating said thin film, wherein said removable protective layer is a flexible low-elastomeric polymer, has stand alone integrity, and is detachable from the master substrate along with carrying the thin film.

34. (canceled)

35. (canceled)

36. (canceled)
